(19) United States
(12) Patent Application Publication
(10) Pub. No.: US 2024/0112963 A1
(43) Pub. Date: Apr. 4, 2024

(54) SEMICONDUCTOR STRUCTURE

(71) Applicant: MEDIATEK INC., Hsinchu City (TW)

(72) Inventors: Yu-Tung CHEN, Hsinchu City (TW); Pei-Haw TSAO, Hsinchu City (TW); Kuo-Lung FAN, Hsinchu City (TW); Yuan-Fu CHUNG, Hsinchu City (TW)

(21) Appl. No.: 18/366,914

(22) Filed: Aug. 8, 2023

Related U.S. Application Data
(60) Provisional application No. 63/377,744, filed on Sep. 30, 2022.

(51) Int. Cl. H01L 21/66

(52) U.S. Cl. CPC H01L 22/32

(57) ABSTRACT

A semiconductor structure is provided. The semiconductor structure includes a semiconductor wafer and a test structure. The semiconductor wafer has a substrate having a scribe line area, a first die area and a second die area. The first die area and the second die area are separated by the scribe line area extending along a first direction. The test structure is disposed in the scribe line area. The test structure includes a test device and a first test pad. The test device has a physical characteristic similar to a semiconductor device fabricated in the first die area or the second die area. The first test pad is electrically connected to the test device. A first distance between the first test pad and the first die area gradually increases from a center region to a peripheral region of the first test pad in the first direction.

### CROSS REFERENCE TO RELATED APPLICATIONS

This application claims the benefit of U.S. Provisional Application No. 63/377,744, filed Sep. 30, 2022, the entirety of which is incorporated by reference herein.

### BACKGROUND OF THE INVENTION

### Field of the Invention

The present invention relates to a semiconductor structure, and, in particular, to a test structure disposed in a scribe line area of a semiconductor wafer.

### Description of the Related Art

During the integrated circuit manufacturing process, integrated circuit (IC) dies are formed on a single semiconductor wafer. The integrated circuit dies are arranged in an array with scribe line areas between them. In addition, the scribe line areas are provided for placement of test keys to test different properties of the semiconductor wafer so as to maintain and assure device quality. After the integrated circuit dies are manufactured on the semiconductor wafer, the integrated circuit dies are separated along the scribe line areas using a singulation process for subsequent packaging processes. However, when the dimensions of the scribe line are shrunk, the singulation process may cause damage to the integrated circuit dies.

Thus, a novel test key structure is needed.

### BRIEF SUMMARY OF THE INVENTION

An embodiment of the present invention provides a semiconductor structure. The semiconductor structure includes a semiconductor wafer and a test structure. The semiconductor wafer has a substrate having a scribe line area, a first die area and a second die area. The first die area and the second die area are separated by the scribe line area extending along a first direction. The test structure is disposed in the scribe line area. The test structure includes a test device and a first test pad. The test device has a physical characteristic similar to a semiconductor device fabricated in the first die area or the second die area. The first test pad is electrically connected to the test device. A first distance between the adjacent edge portions of the first test pad and the first die area gradually changes in the first direction.

An embodiment of the present invention provides a semiconductor structure. The semiconductor structure includes a semiconductor wafer and a test structure. The semiconductor wafer has a substrate having a scribe line area extending along a first direction, a first die area and a second die area. The first die area and the second die area are separated by the scribe line area. The test structure is disposed in the scribe line area and between the first die area and the second die area. The test structure includes a test device and a first test pad. The test device has a physical characteristic similar to a semiconductor device fabricated in one of the first die area and the second die area. The first test pad is electrically connected to the test device. The first test pad is tapered toward to the test device in a plan view.

In addition, an embodiment of the present invention provides a semiconductor structure. The semiconductor structure includes a semiconductor wafer and a test structure. The semiconductor wafer has a substrate having a scribe line area extending along a first direction, a first die area and a second die area. The first die area and the second die area are separated by the scribe line area. The test device has a physical characteristic similar to a semiconductor device fabricated in one of the first die area and the second die area. The first test pad is electrically connected to the test device. A first distance between the first test pad and the first die area gradually increases from a center region to a peripheral region of the first test pad in the first direction.

### BRIEF DESCRIPTION OF THE DRAWINGS

The present invention can be more fully understood by reading the subsequent detailed description and examples with references made to the accompanying drawings, wherein:

FIG. 1 is a schematic top view of a semiconductor wafer in accordance with some embodiments of the disclosure;

FIG. 2 is an enlarged top view of the FIG. 1, showing the arrangement of scribe line areas and die areas;

FIG. 3A is an enlarged top view of the FIG. 2, showing the arrangement of test structures in accordance with some embodiments of the disclosure;

FIG. 3B is a cross-sectional view of the test structure along the A-A′ line of FIG. 3A in accordance with some embodiments of the disclosure;

FIGS. 4A, 4B, 4C, 4D, 4E and 4F are top views of a test pad of the test structure in accordance with some embodiments of the disclosure;

FIGS. 5A, 5B, 5C, 5D, 5E and 5F are top views of a distribution area of a test device of the test structure in accordance with some embodiments of the disclosure; and

FIGS. 6 and 7 are enlarged top views of the FIG. 2, showing the arrangement of test structures in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

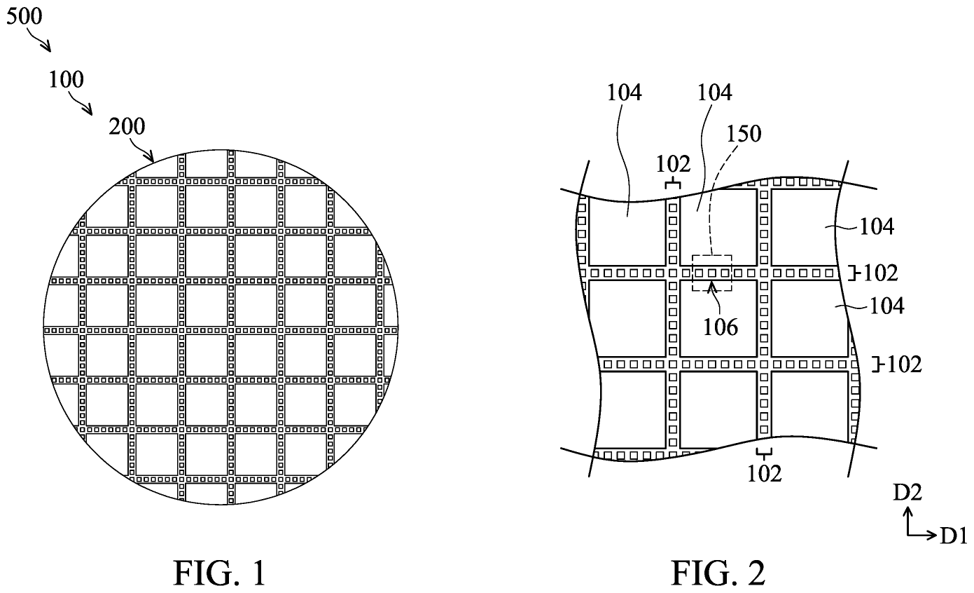

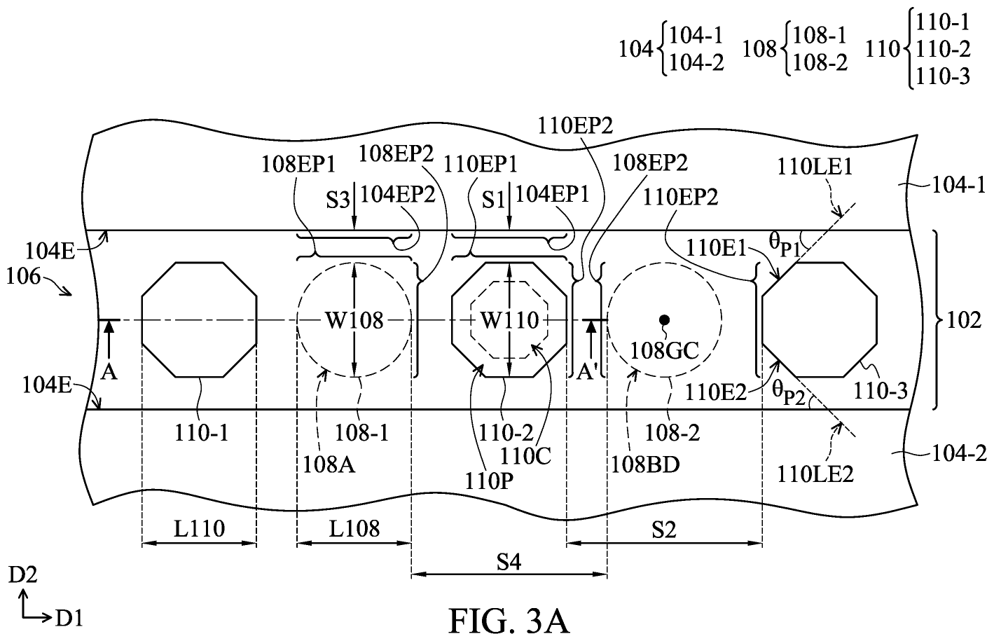

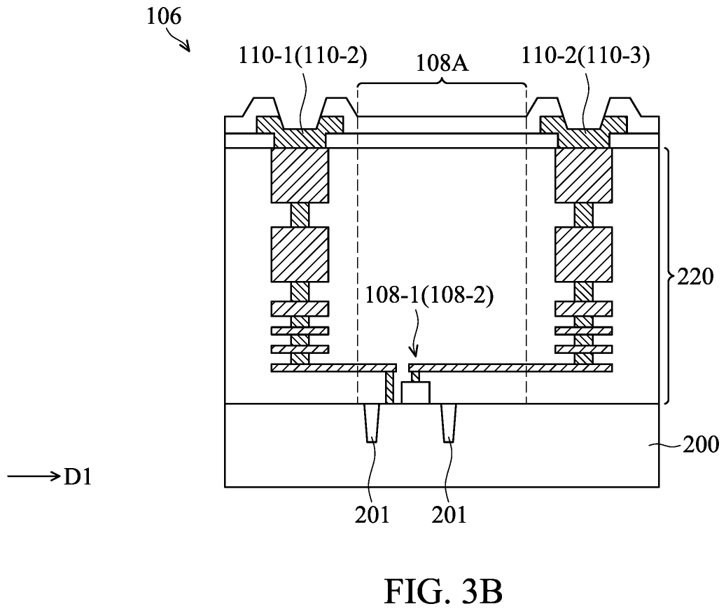

FIG. 1 is a schematic top view of a semiconductor wafer 100 of a semiconductor structure 500 in accordance with some embodiments of the disclosure. FIG. 2 is an enlarged top view of the FIG. 1, showing the arrangement of scribe line areas 102 and die areas 104. As shown in FIGS. 1-2, the semiconductor wafer 100 has a substrate 200 (would be describe in FIG. 3B) having scribe line areas 102 and die areas 104. The adjacent die areas 104 are separated by the scribe line areas 102. In some embodiment, the scribe line areas 102 are defined on the substrate 200 and extend along different directions D1 and D2. In addition, the direction D1 may be substantially perpendicular to the direction D2. In some embodiments, the substrate 200 may comprise silicon. In alternative embodiments, SiGe, bulk semiconductor, strained semiconductor, compound semiconductor, semiconductor-on-insulator (SOI), and other commonly used semiconductor substrates can be used for the substrate 200.

In some embodiment, the scribe line areas 102 are used to separate die areas 104 and provided spaces for the singulation process (including sawing, laser grooving or other applicable singulation processes) to cut the semiconductor wafer 100 into individual semiconductor dies (i.e., the separated die areas 104) without damaging the semiconductor dies. In some embodiment, the scribe line areas 102 are also provided spaces for one or more test structures 106 disposed therein without occupying the space for the die areas 104. In addition, the test structures 106 may be removed after the semiconductor wafer 100 is subjected the singulation process.

FIG. 3A is an enlarged top view of a region 150 of the FIG. 2, showing the arrangement of test structures 106 in accordance with some embodiments of the disclosure. FIG. 3B is a cross-sectional view of the test structure 106 along the A-A′ line of FIG. 3A in accordance with some embodiments of the disclosure. As shown in FIGS. 3A and 3B, the scribe line area 102 extending along the direction D1 separates the adjacent die areas 104-1 and 104-2. The test structure 106 is disposed in the scribe line area 102 and between the die areas 104-1 and 104-2 along the direction D2 in a top view as shown in FIG. 3A.

In some embodiment, the test structure 106 includes a test device 108 (including test devices 108-1 and 108-2) and test pads 110 (including test pads 110-1, 110-2 and 110-3). The test device 108 is formed on the substrate 200 and has a distribution area 108A in the top view as shown in FIG. 3A. In some embodiment, the test device 108 has a physical characteristic similar to a semiconductor device (not shown) fabricated in one of the die areas 104. In addition, the test device 108 and the semiconductor device (not shown) in one of the die areas 104 may be formed using the same fabrication processes. For example, the test device 108 may be a metal-oxide-semiconductor field effect transistor (MOSFET) having a physical structure similar to a MOSFET in one of the die areas 104. In addition, the test device 108 in the scribe line area 102 and the MOSFET in one of the die areas 104 may be formed sing the same fabrication processes. It is noted that the type of the test device 108 is not limited to the disclosed embodiment. For example, the test device 108 may include active devices, passive devices, functional circuits or other applicable devices that are similar to those fabricated in the die areas 104. For example, the test device 108 may include geometric structures similar to various features of the semiconductor devices (e.g., various doped regions, various material layers) in the die areas 104 for the testing of various physical characteristic variables, such as strain, doping type or concentration, the critical dimension of the devices (such as channel length, channel width, gate oxide thickness), electrical performances (such as threshold voltage, saturation current or leakage current), or other useful characteristics. The test structure 106 is deposed in the scribe line areas 102 for testing to ensure that processing of subsequent device elements does not cause the resulting product to fail.

In some embodiment, the substrate 200 further includes one or more isolation features 201 formed in the substrate 200, such as shallow trench isolation (STI) features or local oxidation of silicon (LOCOS) features. The isolation features 201 may surround the test device 108. The isolation features 201 are configured to provide physical and electrical isolation between the test device 108 and other test devices (not shown) in the scribe line area 102 or semiconductor devices (not shown) in the die areas 104.

In some embodiment, the semiconductor structure 500 further includes an interconnection structure 220 formed on the substrate 200 and the test structure 108. In addition, the interconnection structure 220 is configured electrically connected to various terminals of the corresponding test structure 108. In some embodiment, the interconnection structure 220 includes various contacts/vias/conductive traces disposed in multilayer interlayer dielectrics (ILD) (not shown). In some embodiment, the contacts/vias/conductive traces include a conductive material, such as copper (Cu), aluminum (Al), tungsten (W), titanium (Ti), titanium nitride (TiN), tantalum (Ta), tantalum nitride (TaN), or another applicable material. In some embodiment, the interlayer dielectrics may include silicon oxide, silicon oxynitride, un-doped silicate glass (USG), borosilicate glass (BSG), phosphoric silicate glass (PSG), borophosphosilicate glass (BPSG), fluorinated silicate glass (FSG), carbon doped oxide, porous carbon doped silicon dioxide, a polymer such as polyimide or silicon oxycarbide polymer (SiOC), or combinations thereof. The contacts and the vias may be alternately arranged with and electrically connected to the conductive traces belong to various conductive layers of the interconnection structure 220. However, it should be noted that the number of contacts/vias/conductive traces and the number of interlayer dielectrics shown in FIG. 3B is only an example and is not a limitation to the present invention.

As shown in FIG. 3A, the conductive traces of the interconnection structure 220 may be electrically connected to the corresponding test pads 110 (including test pads 110-1, 110-2 and 110-3). In some embodiment, the test pads 110 are portions of a topmost conductive layer of the interconnection structure 220. The test device 108 is disposed below and electrically connected to the test pads 110. In addition, the test device 108 is disposed between the corresponding test pads 110 in the direction D1 as shown in FIGS. 3A and 3B. In some embodiment, the test device 108 and the test pads 110 are alternatively arranged along the direction D1. The test pads 110 are exposed to openings of a passivation layer (not shown). In some embodiment, the test pads 110 are aluminum (Al), copper (Cu). However, it should be noted that the number of test pads 110 shown in FIGS. 1, 2, 3A and 3B is only an example and is not a limitation to the present invention.

In some embodiment, a distance S1 between adjacent edge portions 110EP1 and 104EP1 of the test pad 110 and the die area 104 gradually changes in the direction D1. For example, the distance S1 between adjacent edge portions 110EP1 and 104EP1 of the test pad 110-2 (or the test pads 110-1, 110-3) and the die area 104-1 (or the die area 104-2) may gradually increase from a center region 110C to a peripheral region 110P of the test pad 110-2.

As shown in FIG. 3A, the test pad 110 has a dimension L110 along the direction D1. In some embodiments, the dimension L110 of the test pad 110 gradually changes along a direction D2 that is different from the direction D1. For example, the direction D1 is substantially perpendicular to the direction D2. For example, the dimension L110 of the test pad 110-2 (or the test pads 110-1, 110-3) may gradually decrease from the center region 110C to the peripheral region 110P of the test pad 110-2 along the direction D2. In some embodiments, the test pad 110 is tapered from the center region 110C to the peripheral region 110P of the test pad 110 along the direction D2. That is to say, the test pad 110-1 (or the test pads 110-1, 110-3) may be tapered toward to the adjacent die areas 104-1 and 104-2 in a plan view as shown in FIG. 3A. In some embodiments, the dimension L110 of the test pad 110 has a minimum value in a position that is closest to the die area 104-1 (or the die area 104-2) along the direction D2 in a plan view as shown in FIG. 3A.

As shown in FIG. 3A, the test pad 110 has a dimension W110 along the direction D2. In some embodiments, the dimension W110 gradually changes along the direction D1. For example, the dimension W110 may gradually decrease from the center region 110C to the peripheral region 110P of the test pad 110-2 (or the test pads 110-1, 110-3) along the direction D1. In some embodiments, the test pad 110 is tapered from the center region 110C to the peripheral region 110P of the test pad 110 along the direction D1. That is to say, the test pad 110 is tapered toward to the adjacent test devices 108-1 and 108-2 along the direction D1 in a plan view as shown in FIG. 3A. In some embodiments, the dimension W110 of the test pad 110 has a minimum value in a position that is closest to the test device 108-1 (or the die test device 108-2) along the direction D1 in a plan view as shown in FIG. 3A.

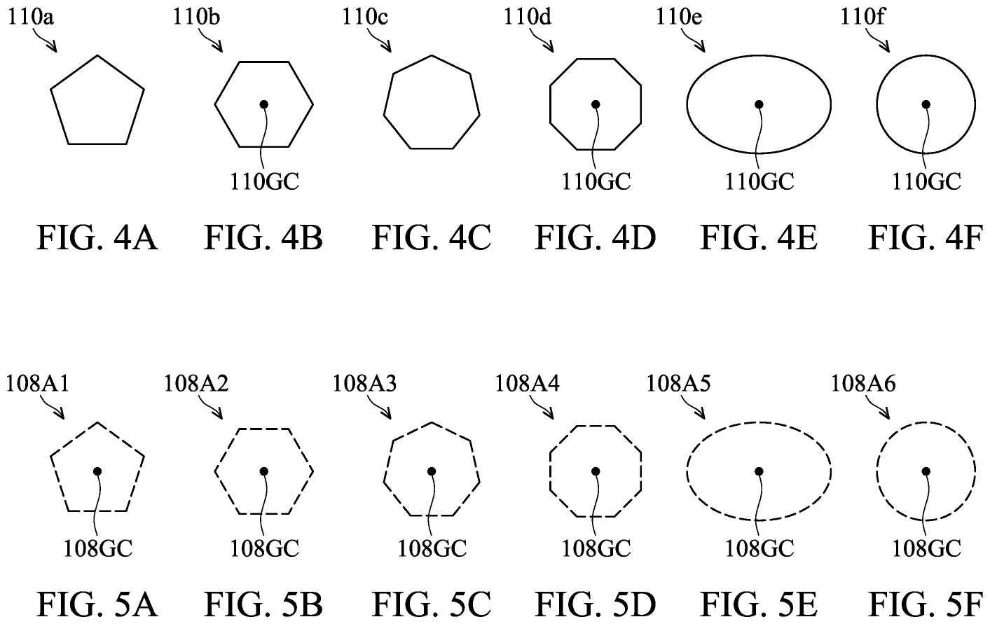

FIGS. 4A, 4B, 4C, 4D, 4E and 4F are top views of the test pad 110 (including test pads 110a, 110b, 110c, 110d, 110e and 1100 of the test structure 106 in accordance with some embodiments of the disclosure. As shown in FIGS. 4A-4F, the test pad 110 may have a shape comprising a polygonal shape with more than four sides (e.g., the test pad 110 may have a pentagonal shape (the test pad 110a shown in FIG. 4A), a hexagonal shape (the test pad 110b shown in FIG. 4B), a heptagonal shape (the test pad 110c shown in FIG. 4C) an octagonal shape (the test pad 110d shown in FIG. 4D)), an oval shape (the test pad 110e shown in FIG. 4E) or a circular shape (the test pad 110f shown in FIG. 4F). In addition, the test pad 110 may have one or more obtuse corners. In some embodiment, the test pad 110 may have polygonal shape with more than four sides with rounded corners.

In some embodiment, the test pads 110b, 110d, 110e and 110f have 2-fold rotational symmetry, which is a 180-degree rotation around geometric centers 110GC of the test pads 110b, 110d, 110e and 110f in a plan view as shown in FIGS. 4B, 4D, 4E and 4F.

In some embodiments that the test pad 110 has a shape comprising a polygonal shape with more than four sides, the test pad 110 has at least one edge with an extended line meeting the edge 104E of the die area 104. For example, the test pad 110-3 (or the test pads 110-1, 110-2) may have an edge 110E1 with an extended line 110LE1 meeting the edge 104E of the die area 104-1. In addition, the test pad 110-3 (or the test pads 110-1, 110-2) may have an edge 110E2 with an extended line 110LE2 meeting the edge 104E of the die area 104-2. In some embodiments, an angle θ_{P1} between the extended line 110LE1 and the edge 104E of the die area 104-1 is an acute angle. In some embodiments, an angle θ_{P2} between the extended line 110LE2 and the edge 104E of the die area 104-2 is an acute angle.

As shown in FIG. 3A, the test pads 110 are arranged side-by-side along the direction D1. In some embodiment, a distance S2 between adjacent edge portions 110EP2 of the adjacent test pads 110 gradually changes in the direction D2. For example, the distance S2 between adjacent edge portions 110EP2 of the adjacent test pads 110-2 and 110-3 (or the adjacent test pads 110-1 and 110-2) may gradually increase from the center region 110C to the peripheral region 110P of the test pad 110-2 (or the test pad 110-3) in the direction D2.

In some embodiment, the geometric shape and the orientation of the distribution area 108A of the test device 108 may be the same or similar to those of the test pad 110 in the plan view as shown in FIG. 3A.

In some embodiment, a distance S3 between adjacent edge portions 108EP1 and 104EP2 of the distribution area 108A of the test device 108 and the die area 104 gradually changes in the direction D1. For example, the distance S3 between adjacent edge portions 108EP1 and 104EP2 of the distribution area 108A of the test device 108-1 (or the test device 108-2) and the die area 104-1 (or the die area 104-2) may gradually increase from to geometric center 108GC to a boundary 108BD of the distribution area 108A of the test device 108-1 (or the test device 108-2) in the direction D1.

As shown in FIG. 3A, the distribution area 108A of the test device 108 has a dimension L108 along the direction D1. In some embodiments, the dimension L108 of the distribution area 108A of the test device 108 gradually changes along the direction D2. For example, the dimension L108 of the distribution area 108A of the test device 108-1 (or the test device 108-2) may gradually decrease from the geometric center 108GC to the boundary 108BD of the distribution area 108A of the test device 108-1 (or the test device 108-2) along the direction D2. In some embodiments, the distribution area 108A of the test device 108-1 (or the test device 108-2) is tapered from the geometric center 108GC to the boundary 108BD of the distribution area 108A of the test device 108-1 (or the test device 108-2) along the direction D2. That is to say, the distribution area 108A of the test device 108-1 (or the test device 108-2) may be tapered toward to the adjacent die areas 104-1 and 104-2 in a plan view as shown in FIG. 3A. In some embodiments, the dimension L108 of the distribution area 108A of the test device 108 has a minimum value in a position that is closest to the die area 104-1 (or the die area 104-2) along the direction D2 in a plan view as shown in FIG. 3A.

As shown in FIG. 3A, the distribution area 108A of the test device 108 has a dimension W108 along the direction D2. In some embodiments, the dimension W108 gradually changes along the direction D1. For example, the dimension W108 may gradually decrease from the geometric center 108GC to the boundary 108BD of the distribution area 108A of the test device 108-1 (or the test device 108-2) along the direction D1. In some embodiments, the distribution area 108A of the test device 108 is tapered from the geometric center 108GC to the boundary 108BD of the distribution area 108A of the test device 108 along the direction D1. That is to say, the distribution area 108A of the test device 108 is tapered toward to the adjacent test pads 110-1, 110-2 and 110-3 along the direction D1 in a plan view as shown in FIG. 3A. In some embodiments, the dimension W108 of the distribution area 108A of the test device 108-1 (or the die test device 108-2) has a minimum value in a position that is closest to the test pad 110-1 (or the test pads 110-2 and 110-3) along the direction D1 in a plan view as shown in FIG. 3A.

FIGS. 5A, 5B, 5C, 5D, 5E and 5F are top views of the distribution area 108A (FIG. 3A) (including distribution areas 108A1, 108A2, 108A3, 108A4, 108A5 and 108A6) of the test device 108 of the test structure in accordance with some embodiments of the disclosure. As shown in FIGS. 5A-5F, the distribution area 108A of the test device 108 may have a shape comprising a polygonal shape with more than four sides (e.g., the distribution area 108A of the test device 108 may have a pentagonal shape (the distribution area 108A1 shown in FIG. 5A), a hexagonal shape (the distribution area 108A2 shown in FIG. 5B), a heptagonal shape (the distribution area 108A3 shown in FIG. 5C) an octagonal shape (the distribution area 108A4 shown in FIG. 5D)), an oval shape (the distribution area 108A5 shown in FIG. 5E) or a circular shape (the distribution area 108A6 shown in FIG. 5F). In addition, the distribution area 108A of the test device 108 may have one or more obtuse corners. In some embodiment, the distribution area 108A of the test device 108 may have polygonal shape with more than four sides with rounded corners.

In some embodiment, the distribution areas 108A2, 108A4, 108A5 and 108A6 have 2-fold rotational symmetry, which is a 180-degree rotation around the geometric centers 108GC of the distribution areas 108A2, 108A4, 108A5 and 108A6, in a plan view as shown in FIGS. 5B, 5D, 5E and 5F.

As shown in FIG. 3A, the test devices 108 may be arranged side-by-side along the direction D1. In some embodiment, a distance S4 between adjacent edge portions 108EP2 of the adjacent test devices 108 gradually changes in the direction D2. For example, the distance S4 between adjacent edge portions 110EP2 of the adjacent test devices 108-1 and 108-2 may gradually increase from the geometric center 108GC to the boundary 108BD of the test device 108-1 (or the test device 108-2) in the direction D2.

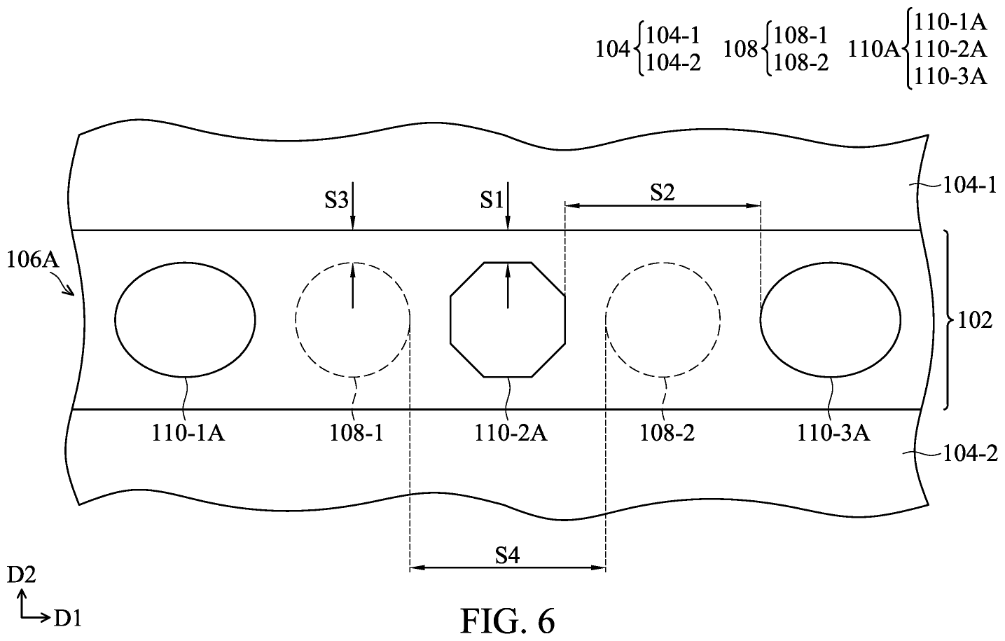

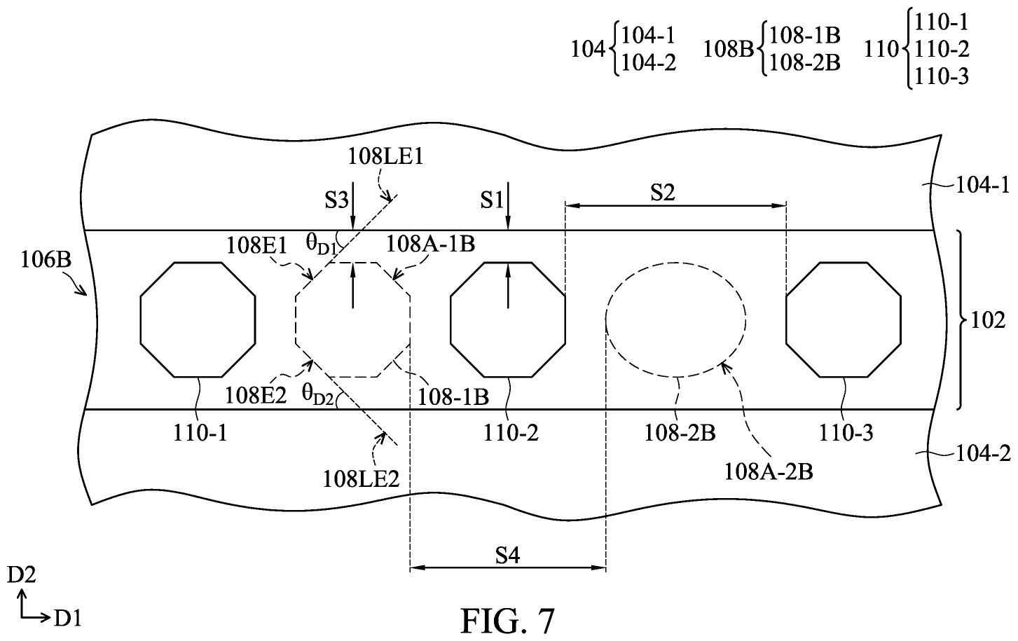

In some embodiment, the adjacent test pads 110 of the test structure 106 may have the same or different the geometric shapes in the top view. In addition, and the distribution areas 108A of the adjacent test devices 108 of the test structure 106 may have the same or different the geometric shapes. FIGS. 6 and 7 are enlarged top views of the FIG. 2, showing the arrangement of the test structures 106A and 106B in accordance with some embodiments of the disclosure. Elements of the embodiments hereinafter, that are the same or similar as those previously described with reference to FIGS. 3A, 3B, 4A-4F and 5A-5F are not repeated for brevity.

As shown in FIG. 6, the difference between the test structure 106 and the test structure 106A is that the test structure 106A includes test pads 110A (including test pads 110-1A, 110-2A and 110-3A) having various geometric shapes in the top view. For example, in the top view as shown in FIG. 3A, all the test pads 110-1, 110-2 and 110-3 are octagonal shape, which is the same or similar as the test pad 110d shown in FIG. 4D. In the top view as shown in FIG. 6, the test pads 110-1A and 110-3A are oval shape, which is the same or similar as the test pad 110e shown in FIG. 4E. In addition, the test pad 110-2A is octagonal shape, which is the same or similar as the test pad 110d shown in FIG. 4D.

As shown in FIG. 7, the difference between the test structure 106 and the test structure 106B is that distribution areas 108A-1B and 108A-2B of the adjacent test devices 108B (including test devices 108-1B and 108-2B) the test structure 106B having various geometric shapes in the top view. For example, in the top view as shown in FIG. 3A, all the distribution areas 108A of the test devices 108-1, 108-2 and 108-3 are circular shape, which is the same or similar as the distribution area 108A6 shown in FIG. 5F. In the top view as shown in FIG. 7, the distribution area 108A-1B of the test device 108-1B is octagonal shape, which is the same or similar as the distribution area 108A4 shown in FIG. 5D. In addition, the distribution area 108A-2B of the test device 108-2B is oval shape, which is the same or similar as the distribution area 108A5 shown in FIG. 5E.

In some embodiments that the distribution area 108A of the adjacent test device 108 has a shape comprising a polygonal shape with more than four sides, the distribution area 108A of the adjacent test device 108 has at least one edge with an extended line meeting the edge 104E of the adjacent die area 104. For example shown in FIG. 7, the distribution area 108A-1B of the test device 108-1B may have an edge 108E1 with an extended line 108LE1 meeting the edge 104E of the die area 104-1. In addition, the distribution area 108A-1B of the test device 108-1B may have an edge 108E2 with an extended line 108LE2 meeting the edge 104E of the die area 104-2. In some embodiments, an angle θ_{D1} between the extended line 108LE1 and the edge 104E of the die area 104-1 is an acute angle. In some embodiments, an angle θ_{D2} between the extended line 108LE2 and the edge 104E of the die area 104-2 is an acute angle.

Laser grooving process is usually used for the semiconductor wafer singulation. In the laser groove process, the laser beam with high temperature emits on the scribe line area of the semiconductor wafer to vaporize various material layers including layers of dielectrics (e.g., oxide or nitride), metals and semiconductors (e.g., silicon) in the semiconductor wafer, results to ablation and latter cut. During the laser grooving process, the test pads and test circuits formed of metals (e.g., Al or Cu), which are designed for electrical test to monitor wafer fabrication processes, easily absorb laser energy than the dielectric layers (e.g., oxide layers) and concentrate heat in site (or corners). In the conventional test devices, the test pads or the distribution area of the test circuits usually have a rectangular shape having 90 degree corners. Boundaries between the 90 degree corners of the test pad or the test circuits and the non-metal area will result in great change in heat absorption. The abrupt change of the laser heat distribution may cause the thermal effect on the adjacent die areas. The thermal effect may result in crack, peeling or delamination at the boundary of the die areas and suffer the reliability of the resulting dies.

Embodiments provide a semiconductor structure including a test structure disposed in a scribe line area of a semiconductor wafer. In some embodiments, the test pads of the test structure and/or the distribution area of the test device may have a shape including a polygonal shape with more than four sides, an oval shape or a circular shape in the top view. In addition, the test pads and/or the distribution area of the test device may have rounded corners or obtuse corners. Furthermore, the test pad may be tapered toward to the adjacent test devices in the plan view. The distribution area of the test device may be tapered toward to the adjacent test pads in the plan view. Therefore, the distance (the distance S1) between adjacent edge portions of the test pad and the adjacent die area gradually changes in the extending direction of the scribe line area (the direction D1). For example, the distance between adjacent edge portions of the test pad and the adjacent die area may gradually increase from the center region to the peripheral region (close to the corners) of the test pad in the extending direction of the scribe line area. In some embodiments, the distance (the distance S2) between adjacent edge portions of the adjacent test pads gradually changes in a direction (the direction D2) that is perpendicular to the extending direction of the scribe line area. For example, the distance between adjacent edge portions of the adjacent test pads may gradually increase from the center region to the peripheral region (close to the corners) of the test pad in a direction that is perpendicular to the extending direction of the scribe line area. In some embodiments, the distance (the distance S3) between the distribution area of the test device and the adjacent die area gradually increases from the geometric center to the boundary of the distribution area in the extending direction of the scribe line area. In some embodiments that the test pad and/or the distribution area of the adjacent test device has a shape comprising a polygonal shape with more than four sides, the test pad and/or the distribution area of the adjacent test device has at least one edge with an extended line meeting the edge of the adjacent die area. The angle (the angles θ_{D1}, θ_{D2}, θ_{P1}, θ_{P2}) between the extended line and the edge of the adjacent die area is an acute angle. During the laser grooving process, the geometric shapes of the test pads of the test structure and/or the distribution area of the test device may result in smooth gradient of laser heat distribution within wafer scribe line area to mitigate the thermal effect on the sidewall of the adjacent die areas. Therefore, reliability of the resulting dies is improved.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a semiconductor wafer having a substrate having a scribe line area, a first die area and a second die area, wherein the first die area and the second die area are separated by the scribe line area extending along a first direction; and
a test structure disposed in the scribe line area, comprising:
a test device having a physical characteristic similar to a semiconductor device fabricated in the first die area or the second die area; and
a first test pad electrically connected to the test device, wherein a first distance between adjacent edge portions of the first test pad and the first die area gradually changes in the first direction.

2. The semiconductor structure as claimed in claim 1, wherein the first distance gradually increases from a center region to a peripheral region of the first test pad.

3. The semiconductor structure as claimed in claim 1, wherein the first test pad has a rounded corner or an obtuse corner.

4. The semiconductor structure as claimed in claim 1, wherein the first test pad has a shape comprising a polygonal shape with more than four sides, an oval shape or a circular shape.

5. The semiconductor structure as claimed in claim 1, wherein the first test pad has 2-fold rotational symmetry, which is a 180-degree rotation around a geometric center of the first test pad, in a plan view.

6. The semiconductor structure as claimed in claim 1, wherein the first test pad has a first dimension along the first direction, wherein the first dimension gradually changes along a second direction that is different from the first direction.

7. The semiconductor structure as claimed in claim 6, wherein the first dimension has a minimum value in a position closest to the first die area in a plan view.

8. The semiconductor structure as claimed in claim 6, wherein the first test pad has a second dimension along the second direction, wherein the second dimension gradually changes along the first direction.

9. The semiconductor structure as claimed in claim 1, wherein the first test pad is tapered from a center region to a peripheral region of the first test pad.

10. The semiconductor structure as claimed in claim 9, wherein the second dimension has a minimum value at a position closest to the test device in a plan view.

11. The semiconductor structure as claimed in claim 1, wherein the first test pad has at least one edge with an extended line meeting a first edge of the first die area, and wherein an angle between the extended line and the first edge of the first die area is an acute angle.

12. The semiconductor structure as claimed in claim 1, wherein the test structure further comprises:
a second test pad arranged beside the first test pad along the first direction, wherein a second distance between adjacent edge portions of the first test pad and the second test pad gradually changes in a second direction that is different from the first direction.

13. The semiconductor structure as claimed in claim 12, wherein the second distance gradually increases from the center region to the peripheral region of the first test pad.

14. The semiconductor structure as claimed in claim 1, wherein the test device is disposed between the first test pad and the second test pad in a plan view.

15. The semiconductor structure as claimed in claim 1, wherein a distribution area of the test device is tapered toward to the first test pad in a plan view.

16. The semiconductor structure as claimed in claim 15, wherein a third distance between adjacent edge portions of the distribution area of the test device and the first die area gradually changes in the first direction.

17. A semiconductor structure, comprising:
a semiconductor wafer having a substrate having a scribe line area, a first die area and a second die area, wherein the first die area and the second die area are separated by the scribe line area extending along a first direction; and
a test structure disposed in the scribe line area and between the first die area and the second die area, comprising:
a test device having a physical characteristic similar to a semiconductor device fabricated in the first die area or the second die area; and
a first test pad electrically connected to the test device, wherein the first test pad is tapered toward to the test device in a plan view.

18. The semiconductor structure as claimed in claim 17, wherein the first test pad is tapered toward to the first die area and the second die area in a plan view.

19. The semiconductor structure as claimed in claim 17, wherein a first distance between the first test pad and the first die area gradually increases from a center region to a peripheral region of the first test pad in the first direction.

20. The semiconductor structure as claimed in claim 17, wherein the first test pad has a rounded corner or an obtuse corner.

21. The semiconductor structure as claimed in claim 17, wherein the first test pad has a shape comprising a polygonal shape with more than four sides, an oval shape or a circular shape.

22. The semiconductor structure as claimed in claim 17, wherein the test structure further comprises:
a second test pad arranged beside the first test pad along the first direction, wherein a second distance between adjacent edge portions of the first test pad and the second test pad gradually increases from a center region to a peripheral region of the first test pad.

23. The semiconductor structure as claimed in claim 17, further comprising:
an interconnection structure formed on the substrate and the test structure, wherein the first test pad and the second test pad are portions of a topmost conductive layer of the interconnection structure.

24. The semiconductor structure as claimed in claim 17, wherein a third distance between a distribution area of the test device and the first die area gradually increases from a geometric center to a boundary of the distribution area in the first direction.

25. A semiconductor structure, comprising:
a semiconductor wafer having a substrate having a scribe line area, a first die area and a second die area, wherein the first die area and the second die area are separated by the scribe line area extending along a first direction; and
a test structure disposed in the scribe line area, comprising:
a test device having a physical characteristic similar to a semiconductor device fabricated in the first die area or the second die area; and
a first test pad electrically connected to the test device, wherein a first distance between the first test pad and the first die area gradually increases from a center region to a peripheral region of the first test pad in the first direction.

26. The semiconductor structure as claimed in claim 25, further comprising:
a second test pad arranged beside the first test pad along the first direction and electrically connected to the test device, wherein a second distance between adjacent edge portions of the first test pad and the second test pad gradually changes in a second direction substantially perpendicular to the first direction.

27. The semiconductor structure as claimed in claim 26, wherein the second distance gradually increases from the center region to the peripheral region of the first test pad.

28. The semiconductor structure as claimed in claim 25, wherein the first test pad has a rounded corner or an obtuse corner.

29. The semiconductor structure as claimed in claim 25, wherein the first test pad has a shape comprising a polygonal shape with more than four sides, an oval shape or a circular shape.

30. The semiconductor structure as claimed in claim 25, wherein a third distance between a distribution area of the test device and the first die area gradually increases from a geometric center to a boundary of the distribution area in the first direction.
